(19) United States
(12) Patent Application Publication
(10) Pub. No.: US 2025/0337211 A1
(43) Pub. Date: Oct. 30, 2025

(54) LASER CHAMBER, DISCHARGE ELECTRODE, AND ELECTRONIC DEVICE MANUFACTURING METHOD

(71) Applicant: Gigaphoton Inc., Tochigi (JP)

(72) Inventor: Kazuki NAGAI, Oyama-shi (JP)

(73) Assignee: Gigaphoton Inc., Tochigi (JP)

(21) Appl. No.: 19/075,321

(22) Filed: Mar. 10, 2025

(30) Foreign Application Priority Data
Apr. 24, 2024 (JP) 2024-070385

(51) Int. Cl. H01S 3/038

(52) U.S. Cl. CPC H01S 3/0385; H01S 3/0381; H01S 3/0382; H01S 3/0388

(57) ABSTRACT

A laser chamber includes a cathode electrode including a cathode discharge surface extending in a first direction, an anode electrode including an anode discharge surface extending in the first direction, the anode discharge surface facing the cathode discharge surface in a second direction orthogonal to the first direction, a fan that circulates the laser gas to pass through a discharge space between the cathode electrode and the anode electrode in a third direction orthogonal to the first direction and the second direction, and a preionization electrode disposed on an upstream side of the laser gas. A cross-sectional shape of the cathode discharge surface cut along a plane orthogonal to the first direction is asymmetrical about an axis parallel to the second direction, and a cross-sectional shape of the anode discharge surface cut along the plane is symmetrical about the axis, in an initial state.

### CROSS-REFERENCE TO RELATED APPLICATIONS

The present application claims the benefit of Japanese Patent Application No. 2024-070385, filed on Apr. 24, 2024, the entire contents of which are hereby incorporated by reference.

### BACKGROUND

### 1. Technical Field

The present disclosure relates to a laser chamber, a discharge electrode, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: Japanese Unexamined Patent Application Publication No. 03-102884
Patent Document 2: Chinese Patent No. 102768926

### SUMMARY

A laser chamber according to one aspect of the present disclosure is used in a gas laser apparatus that excites a laser gas containing fluorine by electric discharge, and includes a cathode electrode, an anode electrode, a fan, and a preionization electrode. The cathode electrode includes a cathode discharge surface extending in a first direction. The anode electrode includes an anode discharge surface extending in the first direction and is disposed in such a posture that the anode discharge surface faces the cathode discharge surface in a second direction orthogonal to the first direction. The fan is configured to circulate the laser gas so as to pass through a discharge space between the cathode electrode and the anode electrode in a third direction orthogonal to the first direction and the second direction. The preionization electrode is disposed on an upstream side of the laser gas relative to the cathode electrode and the anode electrode. A cross-sectional shape of the cathode discharge surface cut along a plane orthogonal to the first direction is asymmetrical about an axis parallel to the second direction, and a cross-sectional shape of the anode discharge surface cut along the plane is symmetrical about the axis, in an initial state.

A discharge electrode according to one aspect of the present disclosure is used in a gas laser apparatus that excites a laser gas containing fluorine by electric discharge, and includes a cathode electrode and an anode electrode. The cathode electrode includes a cathode discharge surface extending in a first direction. The anode electrode includes an anode discharge surface extending in the first direction and is disposed in such a posture that the anode discharge surface faces the cathode discharge surface in a second direction orthogonal to the first direction. A cross-sectional shape of the cathode discharge surface cut along a plane orthogonal to the first direction is asymmetrical about an axis parallel to the second direction, and a cross-sectional shape of the anode discharge surface cut along the plane is symmetrical about the axis, in an initial state.

An electronic device manufacturing method according to one aspect of the present disclosure includes generating a laser beam with a laser apparatus, outputting the laser beam to an exposure apparatus, and exposing a photosensitive substrate to the laser beam within the exposure apparatus to manufacture an electronic device. The gas laser apparatus includes a laser chamber used in the gas laser apparatus that excites a laser gas containing fluorine by electric discharge. The laser chamber includes a cathode electrode including a cathode discharge surface extending in a first direction, an anode electrode including an anode discharge surface extending in the first direction and disposed in such a posture that the anode discharge surface faces the cathode discharge surface in a second direction orthogonal to the first direction, a fan configured to circulate the laser gas so as to pass through a discharge space between the cathode electrode and the anode electrode in a third direction orthogonal to the first direction and the second direction, and a preionization electrode disposed on an upstream side of the laser gas relative to the cathode electrode and the anode electrode. A cross-sectional shape of the cathode discharge surface cut along a plane orthogonal to the first direction is asymmetrical about an axis parallel to the second direction, and a cross-sectional shape of the anode discharge surface cut along the plane is symmetrical about the axis, in an initial state.

### BRIEF DESCRIPTION OF THE DRAWINGS

Some embodiments of the present disclosure will be described below, by way of example only, with reference to the accompanying drawings.

FIG. 1 is a side view schematically illustrating a configuration of a gas laser apparatus according to a comparative example.

FIG. 2 is a sectional view schematically illustrating the configuration of the gas laser apparatus according to the comparative example.

FIG. 3 is a sectional view illustrating a shape of a main electrode according to the comparative example.

FIG. 4 is a graph illustrating a relation between fluorine consumption and operation time during an operation of the gas laser apparatus according to the comparative example.

FIG. 5 is a sectional view illustrating a configuration of a main electrode according to a first embodiment.

FIG. 6 is a diagram illustrating a cross-sectional shape of a first discharge surface.

FIG. 7 is a diagram illustrating a cross-sectional shape of a second discharge surface.

FIG. 8 is a sectional view illustrating a configuration of a main electrode according to a second embodiment.

FIG. 9 is a sectional view illustrating a configuration of a main electrode according to a third embodiment.

FIG. 10 is a sectional view illustrating a configuration of a main electrode according to a modification of the third embodiment.

FIG. 11 is a sectional view illustrating a configuration of a main electrode according to a fourth embodiment.

FIG. 12 is a sectional view illustrating a configuration of a main electrode according to a modification of the fourth embodiment.

FIG. 13 is a sectional view illustrating a method of manufacturing a cathode electrode.

FIG. 14 is a sectional view illustrating a method of manufacturing an anode electrode.

FIG. 15 is a diagram schematically illustrating a configuration example of an exposure apparatus.

### DESCRIPTION OF EMBODIMENTS

### <Contents>

1. Comparative Example
   1.1 Gas Laser Apparatus
      1.1.1 Configuration
      1.1.2 Operation
   1.2 Electrode Shape
   1.3 Problem
2. First Embodiment
   2.1 Configuration
      2.1.1 Cathode Electrode Shape
      2.1.2 Anode Electrode Shape
   2.2 Effect and Advantage
3. Second Embodiment
   3.1 Configuration
      3.1.1 Cathode Electrode Shape
      3.1.2 Anode Electrode Shape
   3.2 Effect and Advantage
4. Third Embodiment
   4.1 Configuration
      4.1.1 Cathode Electrode Shape
      4.1.2 Anode Electrode Shape
   4.2 Effect and Advantage
5. Fourth Embodiment
   5.1 Configuration
      5.1.1 Cathode Electrode Shape
      5.1.2 Anode Electrode Shape
   5.2 Effect and Advantage
6. Main Electrode Manufacturing Method
7. Electronic Device Manufacturing Method

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Comparative Example

First, a comparative example of the present disclosure will be described. The comparative example of the present disclosure is an example recognized by the applicant as known only by the applicant, and is not a publicly known example admitted by the applicant.

### 1.1 Gas Laser Apparatus

### 1.1.1 Configuration

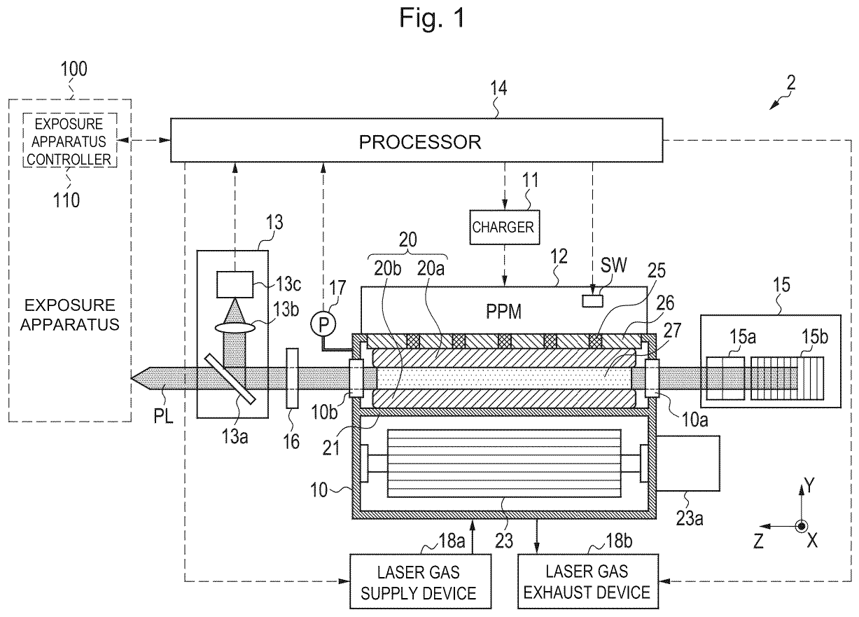

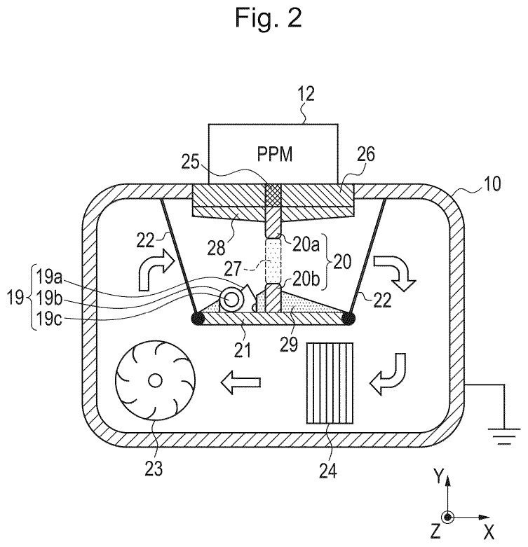

A configuration of a gas laser apparatus 2 according to the comparative example will be described with reference to FIG. 1 and FIG. 2. FIG. 1 schematically illustrates the configuration of the gas laser apparatus 2. FIG. 2 is a sectional view viewing the gas laser apparatus 2 illustrated in FIG. 1 from the Z direction. The gas laser apparatus 2 is a discharge excitation type gas laser apparatus that excites a laser gas by electric discharge, and is, for example, an excimer laser apparatus.

In FIG. 1, a traveling direction of a pulse laser beam PL output from the gas laser apparatus 2 is defined as a Z direction. A discharge direction, to be described later, which is orthogonal to the Z direction is defined as a Y direction. A direction orthogonal to the Z direction and the Y direction is defined as an X direction. The pulse laser beam PL is an example of a “laser beam” according to technology of the present disclosure. The Z direction corresponds to a “first direction” according to the technology of the present disclosure. The Y direction corresponds to a “second direction” according to the technology of the present disclosure. The X direction corresponds to a “third direction” according to the technology of the present disclosure.

In FIG. 1, the gas laser apparatus 2 includes a laser chamber 10, a charger 11, a pulse power module (PPM) 12, a pulse energy measuring unit 13, a processor 14, a pressure sensor 17, and a laser resonator. The laser resonator is formed of a line narrowing module 15 and an output coupling mirror 16.

The laser chamber 10 is, for example, a metal container made of an aluminum metal plated with nickel on a surface thereof. As illustrated in FIG. 1 and FIG. 2, inside the laser chamber 10, a main electrode 20, a ground plate 21, wires 22, a fan 23, a heat exchanger 24, a preionization electrode 19, electrically insulating guides 28, and metal dampers 29 are provided. The main electrode 20 is an example of a “discharge electrode” according to the technology of the present disclosure.

In the laser chamber 10, a laser gas containing fluorine (F₂) is enclosed as a laser medium. The laser gas contains, for example, argon, krypton, and xenon or the like as a rare gas, neon and helium or the like as a buffer gas, and fluorine and chlorine or the like as a halogen gas.

Further, an opening is formed in the laser chamber 10. An electrically insulating plate 26 in which feedthroughs 25 are embedded is attached to the laser chamber 10 via an unillustrated O-ring so as to close the opening. On the electrically insulating plate 26, the PPM 12 is disposed. The laser chamber 10 is grounded.

The PPM 12 includes a charging capacitor to be described later, and is connected to the main electrode 20 via the feedthroughs 25. The PPM 12 includes a switch SW for causing electric discharge to occur in the main electrode 20. The charger 11 is connected to the charging capacitor of the PPM 12. Hereinafter, electric discharge that occurs in the main electrode 20 is referred to as main electric discharge.

The main electrode 20 includes a cathode electrode 20a and an anode electrode 20b extending in the Z direction. The cathode electrode 20a and the anode electrode 20b are disposed in such a posture that their discharge surfaces face each other in the Y direction in the laser chamber 10. A space between the cathode electrode 20a and the anode electrode 20b is referred to as a discharge space 27. The cathode electrode 20a is supported by the electrically insulating plate 26 on a surface opposite to the discharge surface, and is connected to the feedthroughs 25. The anode electrode 20b is supported by the ground plate 21 on a surface opposite to the discharge surface.

The cathode electrode 20a and the anode electrode 20b are each formed of a member containing copper (Cu). For example, the cathode electrode 20a and the anode electrode 20b are formed of copper or brass that is an alloy of copper and zinc (Zn).

The ground plate 21 is connected to the laser chamber 10 via the wires 22. The laser chamber 10 is grounded. Therefore, the ground plate 21 is grounded via the wires 22. Ends of the ground plate 21 in the Z direction are fixed to the laser chamber 10.

The fan 23 is a cross-flow fan for circulating the laser gas in the laser chamber 10, and is disposed on an opposite side of the discharge space 27 with respect to the ground plate 21. A motor 23a for rotationally driving the fan 23 is connected to the laser chamber 10.

The laser gas blown out from the fan 23 flows into the discharge space 27. A flow direction of the laser gas flowing into the discharge space 27 is substantially parallel to the X direction. The laser gas flowing out of the discharge space 27 can be sucked into the fan 23 via the heat exchanger 24. The heat exchanger 24 exchanges heat between a refrigerant supplied into the heat exchanger 24 and the laser gas.

The preionization electrode 19 includes a preionization outer electrode 19a, a dielectric pipe 19b, and a preionization inner electrode 19c, and is disposed on an upstream side of the laser gas relative to the main electrode 20.

The electrically insulating guides 28 are disposed on a surface of the electrically insulating plate 26 on the discharge space 27 side so as to sandwich the cathode electrode 20a. Each electrically insulating guide 28 is formed in a shape to guide a flow of the laser gas such that the laser gas from the fan 23 efficiently flows between the cathode electrode 20a and the anode electrode 20b. The electrically insulating guides 28 and the electrically insulating plate 26 are formed of, for example, ceramic such as alumina (Al₂O₃) having low reactivity with fluorine.

The metal dampers 29 are disposed on a surface of the ground plate 21 on the discharge space 27 side so as to sandwich the anode electrode 20b. Each metal damper 29 is formed of, for example, a porous nickel metal having low reactivity with fluorine.

To the laser chamber 10, a laser gas supply device 18a and a laser gas exhaust device 18b are connected. The laser gas supply device 18a includes a valve and a flow rate control valve, and is connected to a gas cylinder containing the laser gas. The laser gas exhaust device 18b includes a valve and an exhaust pump.

At ends of the laser chamber 10, windows 10a and 10b through which light generated in the laser chamber 10 is output to an outside are provided. The laser chamber 10 is disposed such that an optical path of the optical resonator passes through the discharge space 27 and the windows 10a and 10b.

The line narrowing module 15 includes a prism 15a and a grating 15b. The prism 15a expands a beam width of the light output from the laser chamber 10 through the window 10a and transmits the light toward the grating 15b.

The grating 15b is disposed in Littrow arrangement in which an incident angle and a diffracting angle are the same angle. The grating 15b is a wavelength selecting element that selectively extracts light in a vicinity of a specific wavelength according to the diffracting angle. A spectral width of the light returning from the grating 15b through the prism 15a to the laser chamber 10 is narrowed.

The output coupling mirror 16 transmits a part of the light output from the laser chamber 10 through the window 10b, and reflects the other part back to the laser chamber 10. A surface of the output coupling mirror 16 is coated with a partially reflective film.

The light output from the laser chamber 10 reciprocates between the line narrowing module 15 and the output coupling mirror 16, and is amplified every time it passes through the discharge space 27. A part of the amplified light is output as the pulse laser beam PL through the output coupling mirror 16.

The pulse energy measuring unit 13 is disposed in an optical path of the pulse laser beam PL output through the output coupling mirror 16. The pulse energy measuring unit 13 includes a beam splitter 13a, a focusing optical system 13b, and a photosensor 13c.

The beam splitter 13a transmits the pulse laser beam PL with a high transmittance and reflects a part of the pulse laser beam PL toward the focusing optical system 13b. The focusing optical system 13b focuses the light reflected by the beam splitter 13a on a light receiving surface of the photosensor 13c. The photosensor 13c measures pulse energy of the light focused on the light receiving surface, and outputs a measured value to the processor 14.

The pressure sensor 17 detects a gas pressure in the laser chamber 10, and outputs a detection value to the processor 14. The processor 14 determines a gas pressure of the laser gas in the laser chamber 10 based on the detection value of the gas pressure and a charging voltage Vhv of the charger 11.

The charger 11 is a high voltage power source that supplies the charging voltage Vhv to the charging capacitor included in the PPM 12. The switch SW of the PPM 12 is controlled by the processor 14. When the switch SW is switched from OFF to ON, the PPM 12 generates a high voltage pulse from electric energy stored in the charging capacitor and applies the high voltage pulse to the main electrode 20.

The processor 14 is a processing device that transmits and receives various kinds of signals to and from an exposure apparatus controller 110 provided in an exposure apparatus 100. For example, a signal indicating target pulse energy Et of the pulse laser beam PL to be output to the exposure apparatus 100 and an oscillation trigger signal or the like are transmitted from the exposure apparatus controller 110 to the processor 14.

The processor 14 generally controls operations of components of the gas laser apparatus 2 based on various kinds of signals transmitted from the exposure apparatus controller 110, the measured value of the pulse energy, and the detection value of the gas pressure, or the like.

### 1.1.2 Operation

Next, an operation of the gas laser apparatus 2 according to the comparative example will be described. First, the processor 14 controls the laser gas supply device 18a to supply the laser gas into the laser chamber 10, and drives the motor 23a to rotate the fan 23. Accordingly, the laser gas in the laser chamber 10 is circulated.

The processor 14 receives the signal indicating the target pulse energy Et and the oscillation trigger signal transmitted from the exposure apparatus controller 110. The oscillation trigger signal is a signal that instructs the gas laser apparatus 2 to output the pulse laser beam PL for one pulse.

The processor 14 sets the charging voltage Vhv corresponding to the target pulse energy Et in the charger 11. The processor 14 operates the switch SW of the PPM 12 in synchronization with the oscillation trigger signal.

When the switch SW of PPM 12 is switched from OFF to ON, a voltage is applied between the preionization inner electrode 19c and the preionization outer electrode 19a of the preionization electrode 19 and between the cathode electrode 20a and the anode electrode 20b. Thus, corona discharge occurs in the preionization electrode 19, and ultraviolet (UV) light is generated. When the laser gas in the discharge space 27 is irradiated with the UV light, the laser gas is preionized.

Thereafter, when the voltage between the cathode electrode 20a and the anode electrode 20b reaches a breakdown voltage, the main electric discharge occurs in the discharge space 27. When a discharge direction of the main electric discharge refers to the direction in which electrons flow, the discharge direction is the direction from the cathode electrode 20a toward the anode electrode 20b. When the main electric discharge occurs, the laser gas in the discharge space 27 is excited to output light.

The metal dampers 29 suppress acoustic waves generated by the main electric discharge from being reflected back to the discharge space 27 again. Further, as the laser gas is circulated in the laser chamber 10, a discharge product generated in the discharge space 27 moves downstream.

The light output from the laser gas is reflected by the line narrowing module 15 and the output coupling mirror 16 so that the light reciprocates in the laser resonator, resulting in laser oscillation. The light narrowed by the line narrowing module 15 is output through the output coupling mirror 16 as the pulse laser beam PL.

The pulse laser beam PL output through the output coupling mirror 16 enters the pulse energy measuring unit 13. The pulse energy measuring unit 13 measures pulse energy E of a part of the pulse laser beam PL that has entered, and outputs a measured value to the processor 14.

The processor 14 calculates a difference ΔE between the measured value of the pulse energy E and the target pulse energy Et. The processor 14 feedback-controls the charging voltage Vhv based on the difference ΔE so that the measured value of the pulse energy E is equal to the target pulse energy Et.

When the charging voltage Vhv becomes higher than a maximum value in an allowable range, the processor 14 controls the laser gas supply device 18a to supply the laser gas into the laser chamber 10 until a predetermined pressure is attained. When the charging voltage Vhv becomes lower than a minimum value in the allowable range, the processor 14 controls the laser gas exhaust device 18b to exhaust the laser gas from the laser chamber 10 until the predetermined pressure is attained.

Note that the gas laser apparatus 2 is not necessarily limited to a line narrowing laser apparatus, and may be a laser apparatus that outputs spontaneous oscillation light. For example, instead of the line narrowing module 15, a high reflective mirror may be disposed.

Further, while an excimer laser apparatus is exemplified as the gas laser apparatus 2 in FIG. 1 and FIG. 2, the gas laser apparatus 2 may be an F₂ laser apparatus using a laser gas including a fluorine gas and a buffer gas.

### 1.2 Electrode Shape

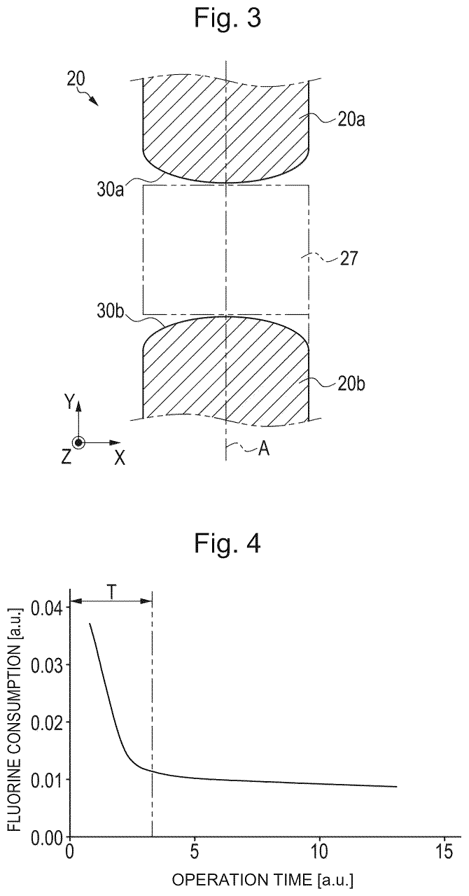

FIG. 3 illustrates a shape of the main electrode 20 according to the comparative example. FIG. 3 illustrates a cross section of the cathode electrode 20a and the anode electrode 20b cut along an XY plane orthogonal to the Z direction. A discharge surface 30a of the cathode electrode 20a and a discharge surface 30b of the anode electrode 20b each have a cross-sectional shape symmetrical about an axis A parallel to the Y direction. Hereinafter, the discharge surface 30a of the cathode electrode 20a is referred to as a “cathode discharge surface 30a”, and the discharge surface 30b of the anode electrode 20b is referred to as an “anode discharge surface 30b”. In addition, in the present disclosure, the cross-sectional shape refers to a shape of a cross section cut along the XY plane. The XY plane corresponds to a “plane orthogonal to a first direction” according to the technology of the present disclosure.

In the comparative example, each of the cross-sectional shapes of the cathode discharge surface 30a and the anode discharge surface 30b has a smooth curved shape, for example, a semi-elliptical shape.

### 1.3 Problem

One of factors determining a service life of the laser chamber 10 is consumption of the main electrode 20. The consumption of the main electrode 20 is related to consumption of fluorine contained in the laser gas in the laser chamber 10 during an operation of the gas laser apparatus 2, and as the consumption of the fluorine increases, the consumption of the main electrode 20 increases. It is considered that the consumption of the main electrode 20 is caused by the consumption of the fluorine due to its bonding with copper or the like contained in the main electrode 20.

FIG. 4 illustrates a relation between the fluorine consumption and operation time during the operation of the gas laser apparatus 2 according to the comparative example. FIG. 4 illustrates a transition of the fluorine consumption until the number of pulses of the pulse laser beam PL reaches about 10 Bpls. According to FIG. 4, it can be seen that the fluorine consumption is large in an initial period T immediately after the operation of the gas laser apparatus 2 is started, and the fluorine consumption gradually decreases after the initial period T.

Therefore, in order to improve the service life of the laser chamber 10, it is effective to suppress the consumption of the main electrode 20 immediately after the operation is started, and for this purpose, it is necessary to suppress the fluorine consumption immediately after the operation is started.

An object of the technology of the present disclosure is to improve the service life of the laser chamber 10 by suppressing the consumption of the main electrode 20.

### 2. First Embodiment

### 2.1 Configuration

The gas laser apparatus 2 according to a first embodiment of the present disclosure has the same configuration as the gas laser apparatus 2 according to the comparative example except that a shape of the main electrode 20 is different.

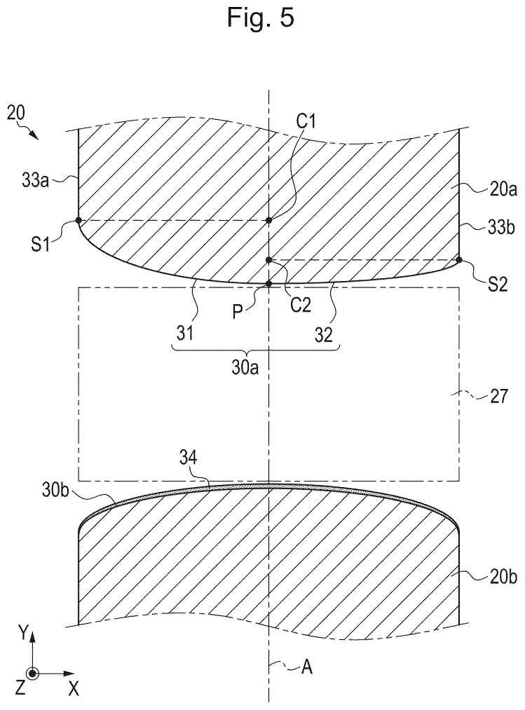

FIG. 5 illustrates a configuration of the main electrode 20 according to the first embodiment. FIG. 5 illustrates a cross section of the cathode electrode 20a and the anode electrode 20b cut along the XY plane. In the present embodiment, the cross-sectional shape of the anode discharge surface 30b is symmetrical about the axis A parallel to the Y direction as in the comparative example. On the other hand, the cross-sectional shape of the cathode discharge surface 30a is asymmetrical about the axis A. The shape of the main electrode 20 of the present embodiment imitates an electrode shape at the end of the life after a lapse of the initial period T illustrated in FIG. 4.

### 2.1.1 Cathode Electrode Shape

In the present embodiment, the cathode discharge surface 30a includes a first discharge surface 31 and a second discharge surface 32 having different cross-sectional shapes. The first discharge surface 31 is positioned on the upstream side of the laser gas relative to the axis A. The second discharge surface 32 is positioned on a downstream side of the laser gas relative to the axis A. The first discharge surface 31 and the second discharge surface 32 are connected at a point P on the axis A.

In the present embodiment, the cross-sectional shape of the first discharge surface 31 and the cross-sectional shape of the second discharge surface 32 each are a part of an elliptical shape, but have different ellipticities. An ellipticity is a ratio of a major diameter and a minor diameter of an ellipse, and is a value obtained by dividing the minor diameter by the major diameter.

Specifically, the cross-sectional shape of the first discharge surface 31 is a part of an elliptical shape which is centered on a point C1 on the axis A and is flattened in the Y direction. The cross-sectional shape of the second discharge surface 32 is a part of an elliptical shape which is centered on a point C2 on the axis A and is flattened in the Y direction. Short axes of both elliptical shapes are parallel to the Y direction and long axes are parallel to the X direction. Each of the cross-sectional shape of the first discharge surface 31 and the cross-sectional shape of the second discharge surface 32 is one of shapes obtained by dividing the elliptical shape into four parts along the short axis and the major axis.

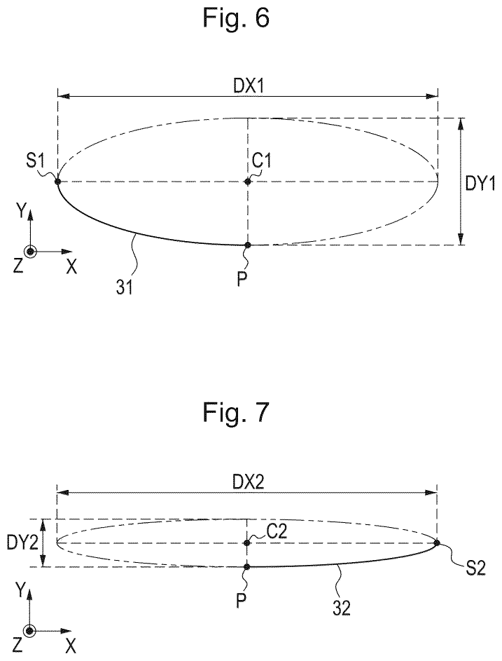

The first discharge surface 31 is connected to a side face 33a on the upstream side of the cathode electrode 20a at a point S1. The point S1 is positioned on the major axis passing through the point C1. Hereinafter, the point S1 is also referred to as an “upstream corner S1”. As illustrated in FIG. 6, when the length of the major axis of an ellipse forming the cross-sectional shape of the first discharge surface 31 is defined as DX1 and the length of the minor axis is defined as DY1, an ellipticity DY1/DX1 is in a range of ⅕ to ⅓.

The second discharge surface 32 is connected to a side face 33b on the downstream side of the cathode electrode 20a at a point S2. The point S2 is positioned on a major axis passing through the point C2. Hereinafter, the point S2 is also referred to as a “downstream corner S2”. As illustrated in FIG. 7, when the length of the major axis of an ellipse forming the cross-sectional shape of the second discharge surface 32 is defined as DX2 and the length of the minor axis is defined as DY2, an ellipticity DY2/DX2 is in a range of 1/10 to ⅛.

The side faces 33a and 33b are parallel to a YZ plane and face each other in the X direction. In addition, the following relations are satisfied: DX1=DX2 and DY1>DY2.

Therefore, the upstream corner S1 of the cathode discharge surface 30a is located farther away from the discharge space 27 in the Y direction than the downstream corner S2. A curvature of the first discharge surface 31 is larger than a curvature of the second discharge surface 32. Note that, in the present disclosure, the discharge space 27 is defined as a space formed between an XZ plane passing through a top of the cathode electrode 20a and an XZ plane passing through a top of the anode electrode 20b. The top of the cathode electrode 20a refers to a portion that protrudes most toward the anode electrode 20b on the cathode discharge surface 30a. The top of the anode electrode 20b refers to a portion that protrudes most toward the cathode electrode 20a on the anode discharge surface 30b. That is, the upstream corner S1 of the cathode discharge surface 30a is located farther away from the top of the cathode electrode 20a in the Y direction than the downstream corner S2.

A coating film is not formed on the first discharge surface 31 and the second discharge surface 32.

### 2.1.2 Anode Electrode Shape

The cross-sectional shape of the anode discharge surface 30b is symmetrical about the axis A and is a part of an elliptical shape that is flattened in the Y direction as in the comparative example. Specifically, the cross-sectional shape of the anode discharge surface 30b is a semi-elliptical shape, and an ellipticity is in a range of ⅙ to ¼. The anode electrode 20b is formed so as to have the same width in the X direction as that of the cathode electrode 20a.

A coating film 34 is formed on the anode discharge surface 30b. For example, a material of the coating film 34 is a mixture of copper and ceramic.

The cross-sectional shape of the main electrode 20 according to the present embodiment has a shape in an initial state. The initial state refers to a state of the main electrode 20 before being attached to the laser chamber 10 at the time of manufacturing the gas laser apparatus 2, or a state of the main electrode 20 at which discharge has not occur even once after being attached to the laser chamber 10.

### 2.2 Effect and Advantage

After starting the operation of the gas laser apparatus 2 according to the comparative example, the applicant observed the shape of the main electrode 20 at the end of the life. As such, the applicant has found that the anode electrode 20b is worn symmetrically on the upstream side and the downstream side about the axis A, whereas the cathode electrode 20a is worn asymmetrically on the upstream side and the downstream side about the axis A. The cathode electrode 20a at the end of the life is worn more on the upstream side than on the downstream side. This is considered to be because an amount of electrons generated by preionization is larger on the upstream side than on the downstream side since the preionization electrode 19 is disposed on the upstream side of the main electrode 20.

In view of the phenomenon observed by the gas laser apparatus 2 according to the comparative example, the applicant makes the main electrode 20 in the initial state have the shape imitating the electrode shape at the end of the life in the present embodiment. That is, the cross-sectional shape of the cathode discharge surface 30a is made asymmetrical about the axis A, and the cross-sectional shape of the anode discharge surface 30b is made symmetrical about the axis A.

Note that only the cathode discharge surface 30a is made asymmetrical in the present embodiment since the anode discharge surface 30b asymmetrical about the axis A gradually changes to have a symmetrical shape with the lapse of the operation time.

Since the fluorine consumption is small and the consumption of the main electrode 20 is suppressed after the lapse of the initial period T in the comparative example as illustrated in FIG. 4, the consumption of the main electrode 20 of the present embodiment imitating the electrode shape at the end of the life is suppressed immediately after the operation of the gas laser apparatus 2 is started. This improves the service life of the laser chamber 10.

In addition, the variation of the pulse energy of the pulse laser beam PL increases when the main electrode 20 is consumed and the shape is greatly changed, but the variation of the pulse energy is suppressed according to the present embodiment since low consumption of the main electrode 20 suppresses a shape change.

Further, even if a coating film is formed on the cathode discharge surface 30a, the coating film would be completely lost until the end of the life, and therefore the coating film 34 is not formed on the cathode discharge surface 30a in the present embodiment. On the other hand, since the anode discharge surface 30b becomes brittle by being fluorinated by fluorine contained in the laser gas, the coating film 34 is formed on the anode discharge surface 30b. The coating film 34 can suppress the shape change of the anode discharge surface 30b.

### 3. Second Embodiment

### 3.1 Configuration

The gas laser apparatus 2 according to a second embodiment of the present disclosure has the same configuration as the gas laser apparatus 2 according to the first embodiment except that the shape of the main electrode 20 is different.

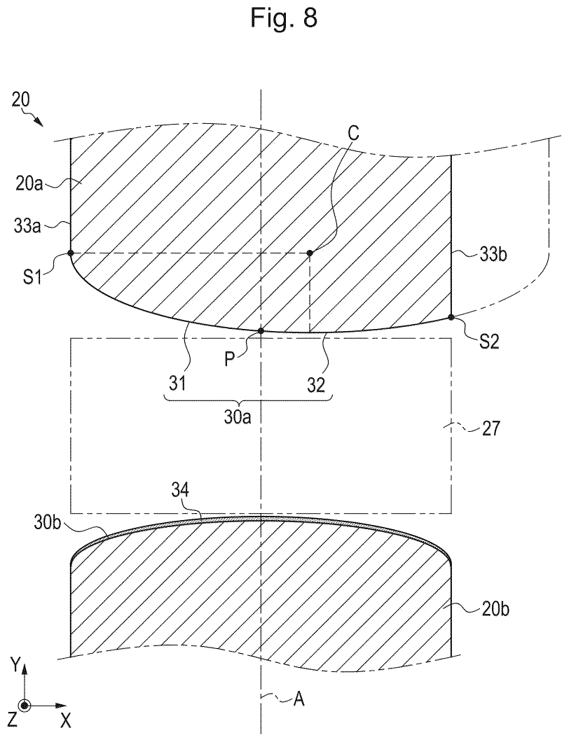

FIG. 8 illustrates a configuration of the main electrode 20 according to the second embodiment. FIG. 8 illustrates a cross section of the cathode electrode 20a and the anode electrode 20b cut along the XY plane. As in the first embodiment, the shape of the main electrode 20 of the present embodiment imitates the electrode shape at the end of the life.

### 3.1.1 Cathode Electrode Shape

The cathode discharge surface 30a includes the first discharge surface 31 and the second discharge surface 32 as in the first embodiment. The first discharge surface 31 and the second discharge surface 32 are connected at the point P on the axis A and are asymmetrical about the axis A.

In the present embodiment, both the cross-sectional shape of the first discharge surface 31 and the cross-sectional shape of the second discharge surface 32 are a part of the same elliptical shape which is centered on a point C positioned on the downstream side relative to the axis A and is flattened in the Y direction. Specifically, the cross-sectional shape of the cathode discharge surface 30a of the present embodiment has a shape obtained by cutting and removing a part on the downstream side of a semi-elliptical shape made by cutting an elliptical shape centered on the point C along the major axis. An ellipticity of the elliptical shape is in the range of ⅕ to ⅓.

As in the first embodiment, the upstream corner S1 is positioned on a major axis passing through the point C. In the present embodiment, the downstream corner S2 is positioned at an end formed by cutting a part on the downstream side of the semi-elliptical shape. Therefore, in the present embodiment as well, the upstream corner S1 of the cathode discharge surface 30a is located farther away from the discharge space 27 than the downstream corner S2. The curvature of the first discharge surface 31 is larger than the curvature of the second discharge surface 32.

### 3.1.2 Anode Electrode Shape

The anode electrode 20b has the same configuration as that of the first embodiment. The anode electrode 20b is formed so as to have the same width in the X direction as that of the cathode electrode 20a.

### 3.2 Effect and Advantage

The gas laser apparatus 2 according to the second embodiment has the same effects and advantages as those of the gas laser apparatus 2 according to the first embodiment.

### 4. Third Embodiment

### 4.1 Configuration

The gas laser apparatus 2 according to a third embodiment of the present disclosure has the same configuration as the gas laser apparatus 2 according to the first embodiment except that the shape of the main electrode 20 is different.

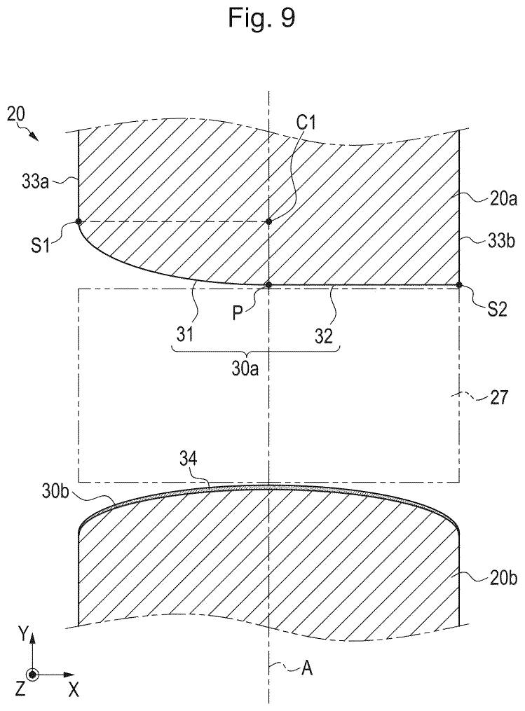

FIG. 9 illustrates a configuration of the main electrode 20 according to the third embodiment. FIG. 9 illustrates a cross section of the cathode electrode 20a and the anode electrode 20b cut along the XY plane. As in the first embodiment, the shape of the main electrode 20 of the present embodiment imitates the electrode shape at the end of the life.

### 4.1.1 Cathode Electrode Shape

The cathode discharge surface 30a includes the first discharge surface 31 and the second discharge surface 32 as in the first embodiment. The first discharge surface 31 and the second discharge surface 32 are connected at the point P on the axis A and are asymmetrical about the axis A.

The cross-sectional shape of the cathode discharge surface 30a of the present embodiment differs from the cross-sectional shape of the cathode discharge surface 30a of the first embodiment only in the cross-sectional shape of the second discharge surface 32. As in the first embodiment, the cross-sectional shape of the first discharge surface 31 of the present embodiment is a part of an elliptical shape which has an ellipticity in a range of ⅕ to ⅓ and is flattened in the Y direction. The cross-sectional shape of the second discharge surface 32 of the present embodiment has a linear shape parallel to the X direction. That is, the second discharge surface 32 is a flat surface.

In the present embodiment as well, the upstream corner S1 of the cathode discharge surface 30a is located farther away from the discharge space 27 in the Y direction than the downstream corner S2. The curvature of the first discharge surface 31 is larger than the curvature of the second discharge surface 32.

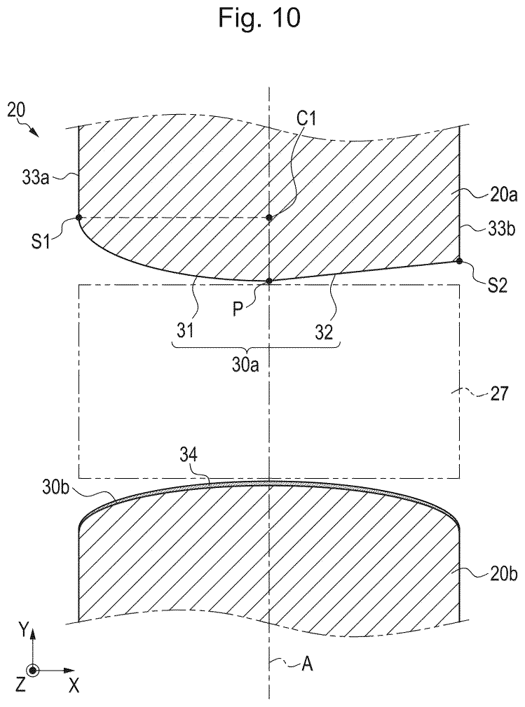

As illustrated in FIG. 10, the cross-sectional shape of the second discharge surface 32 may have a linear shape inclined at a predetermined angle with respect to the X direction. An inclination angle of the second discharge surface 32 with respect to the X direction is preferably determined such that the upstream corner S1 is located farther away from the discharge space 27 than the downstream corner S2. A connecting portion of the first discharge surface 31 and the second discharge surface 32 is preferably rounded with a radius.

### 4.1.2 Anode Electrode Shape

The anode electrode 20b has the same configuration as that of the first embodiment. The anode electrode 20b is formed so as to have the same width in the X direction as that of the cathode electrode 20a.

### 4.2 Effect and Advantage

The gas laser apparatus 2 according to the third embodiment has the same effects and advantages as those of the gas laser apparatus 2 according to the first embodiment.

### 5. Fourth Embodiment

### 5.1 Configuration

The gas laser apparatus 2 according to a fourth embodiment of the present disclosure has the same configuration as the gas laser apparatus 2 according to the first embodiment except that the shape of the main electrode 20 is different.

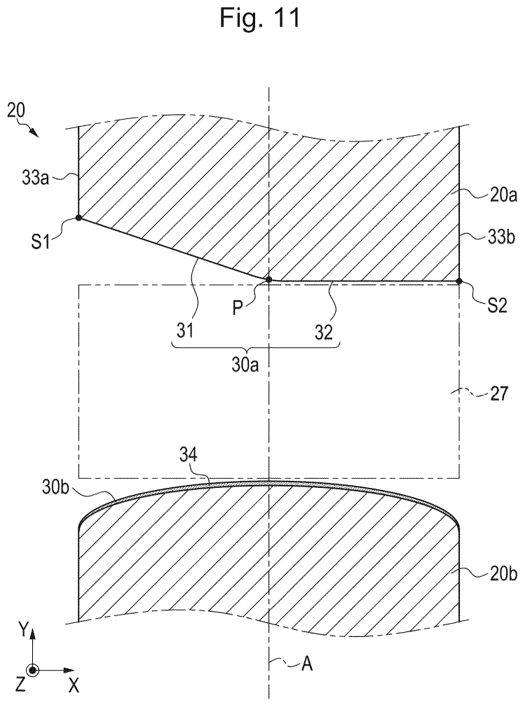

FIG. 11 illustrates a configuration of the main electrode 20 according to the fourth embodiment. FIG. 11 illustrates a cross section of the cathode electrode 20a and the anode electrode 20b cut along the XY plane. As in the first embodiment, the shape of the main electrode 20 of the present embodiment imitates the electrode shape at the end of the life.

### 5.1.1 Cathode Electrode Shape

The cathode discharge surface 30a includes the first discharge surface 31 and the second discharge surface 32 as in the first embodiment. The first discharge surface 31 and the second discharge surface 32 are connected at the point P on the axis A and are asymmetrical about the axis A.

The cross-sectional shape of the cathode discharge surface 30a of the present embodiment differs from the cross-sectional shape of the cathode discharge surface 30a of the third embodiment only in the cross-sectional shape of the first discharge surface 31. The cross-sectional shape of the first discharge surface 31 of the present embodiment has a linear shape inclined at a predetermined angle with respect to the X direction. As in the third embodiment, the cross-sectional shape of the second discharge surface 32 of the present embodiment has a linear shape parallel to the X direction. That is, each of the first discharge surface 31 and the second discharge surface 32 is a flat surface.

The inclination angle of the first discharge surface 31 with respect to the X direction is preferably determined such that the upstream corner S1 is located farther away from the discharge space 27 than the downstream corner S2. Further, a connecting portion of the first discharge surface 31 and the second discharge surface 32 is preferably rounded with a radius.

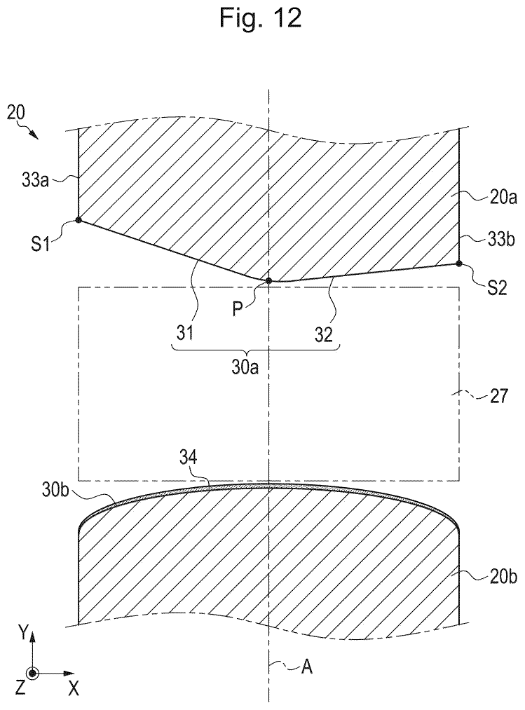

As illustrated in FIG. 12, the cross-sectional shape of the second discharge surface 32 may have a linear shape inclined at a predetermined angle with respect to the X direction. In this case as well, an inclination angle of the second discharge surface 32 with respect to the X direction is preferably determined such that the upstream corner S1 is located farther away from the discharge space 27 than the downstream corner S2.

### 5.1.2 Anode Electrode Shape

The anode electrode 20b has the same configuration as that of the first embodiment. The anode electrode 20b is formed so as to have the same width in the X direction as that of the cathode electrode 20a.

### 5.2 Effect and Advantage

The gas laser apparatus 2 according to the fourth embodiment has the same effects and advantages as those of the gas laser apparatus 2 according to the first embodiment.

### 6. Main Electrode Manufacturing Method

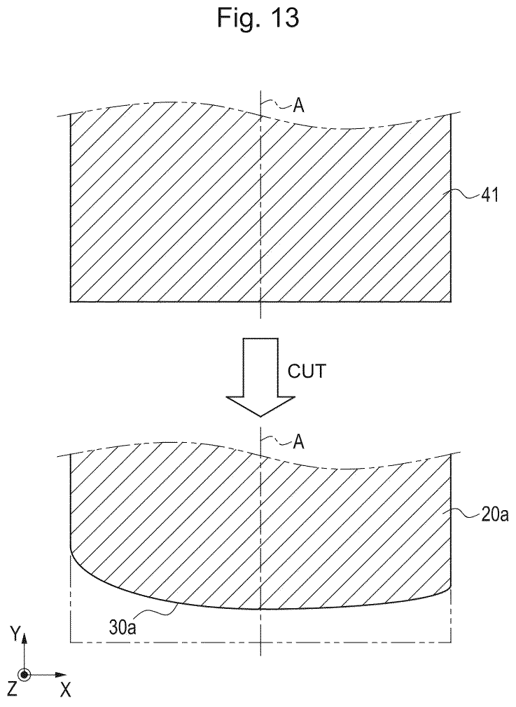

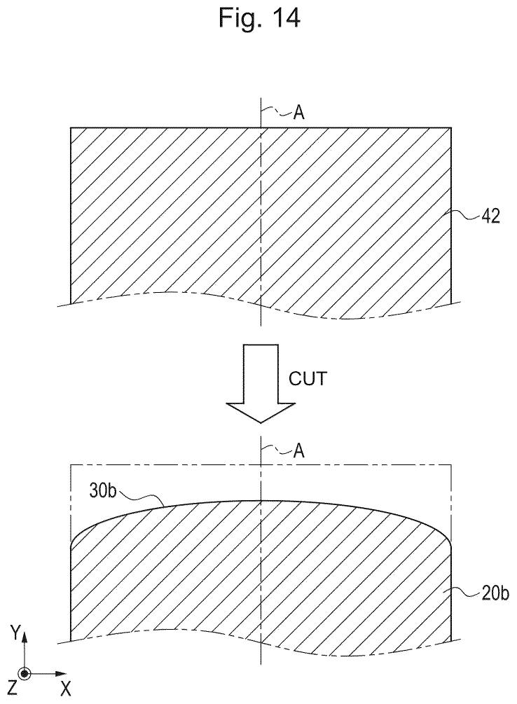

Next, a method of manufacturing the main electrode 20 according to the first embodiment will be described. First, as illustrated in FIG. 13, a base material 41 which is made of a material containing copper and is in a rectangular parallelepiped shape is prepared, and the base material 41 is cut asymmetrically about the axis A from one surface to form the cathode electrode 20a. The cathode discharge surface 30a having the shape described in the first embodiment is formed on the cathode electrode 20a.

Further, as illustrated in FIG. 14, a base material 42 which is made of a material containing copper and is in a rectangular parallelepiped shape is prepared, and the base material 42 is cut symmetrically about the axis A from one surface to form the anode electrode 20b. An anode discharge surface 30b having the shape described as the first embodiment is formed on the anode electrode 20b. Thereafter, the coating film 34 is formed on the anode discharge surface 30b.

Then, the cathode electrode 20a and the anode electrode 20b are mounted in the laser chamber 10. The main electrode 20 thus manufactured has the shape described in the first embodiment in the initial state immediately after manufacturing.

The same applies to the method of manufacturing the main electrodes 20 according to the second to fourth embodiments, and the manufactured main electrodes 20 have the shapes described in the second to fourth embodiments in the initial state immediately after manufacturing.

### 7. Electronic Device Manufacturing Method

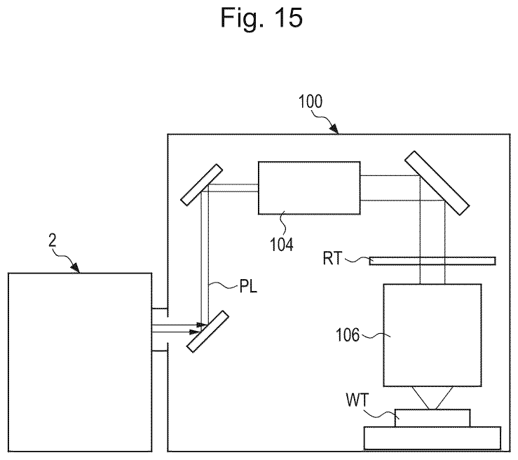

FIG. 15 schematically illustrates a configuration example of the exposure apparatus 100. The exposure apparatus 100 includes an illumination optical system 104 and a projection optical system 106. The illumination optical system 104 illuminates a reticle pattern of an unillustrated reticle disposed on a reticle stage RT with the pulse laser beam PL incoming from the gas laser apparatus 2. The projection optical system 106 performs reduced projection of the pulse laser beam PL transmitted through the reticle, and forms an image on an unillustrated workpiece disposed on a workpiece table WT. The workpiece is a photosensitive substrate such as a semiconductor wafer on which photoresist is applied.

The exposure apparatus 100 synchronously translates the reticle stage RT and the workpiece table WT to expose the workpiece to the pulse laser beam PL reflecting the reticle pattern. After the reticle pattern is transferred onto the semiconductor wafer by the exposure process as above, a semiconductor device can be manufactured through a plurality of processes. The semiconductor device is an example of an “electronic device” in the present disclosure.

Note that the gas laser apparatus 2 may be used not only for manufacturing of an electronic device but also for laser processing such as drilling.

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser chamber to be used in a gas laser apparatus that excites a laser gas containing fluorine by electric discharge, the laser chamber comprising:
a cathode electrode including a cathode discharge surface extending in a first direction;
an anode electrode including an anode discharge surface extending in the first direction and disposed in such a posture that the anode discharge surface faces the cathode discharge surface in a second direction orthogonal to the first direction;
a fan configured to circulate the laser gas so as to pass through a discharge space between the cathode electrode and the anode electrode in a third direction orthogonal to the first direction and the second direction; and
a preionization electrode disposed on an upstream side of the laser gas relative to the cathode electrode and the anode electrode,
a cross-sectional shape of the cathode discharge surface cut along a plane orthogonal to the first direction being asymmetrical about an axis parallel to the second direction, and a cross-sectional shape of the anode discharge surface cut along the plane being symmetrical about the axis, in an initial state.

2. The laser chamber according to claim 1, wherein
a corner of the cathode discharge surface on the upstream side of the laser gas is located farther away from the discharge space in the second direction than a corner of the cathode discharge surface on a downstream side of the laser gas.

3. The laser chamber according to claim 2, wherein
when the cathode discharge surface has a first discharge surface on the upstream side of the laser gas relative to the axis and has a second discharge surface on the downstream side of the laser gas relative to the axis, a curvature of the first discharge surface is larger than a curvature of the second discharge surface.

4. The laser chamber according to claim 3, wherein
a cross-sectional shape of the first discharge surface is a part of an elliptical shape which has an ellipticity in a range of ⅕ to ⅓ and is flattened in the second direction, and
a cross-sectional shape of the second discharge surface is a part of an elliptical shape which has an ellipticity in a range of 1/10 to ⅛ and is flattened in the second direction.

5. The laser chamber according to claim 3, wherein
the cross-sectional shape of the cathode discharge surface is a part of an elliptical shape which is centered on a point positioned on the downstream side of the laser gas relative to the axis, has an ellipticity in a range of ⅕ to ⅓, and is flattened in the second direction.

6. The laser chamber according to claim 3, wherein
a cross-sectional shape of the first discharge surface is a part of an elliptical shape which has an ellipticity in a range of ⅕ to ⅓ and is flattened in the second direction, and a cross-sectional shape of the second discharge surface has a linear shape parallel to the third direction or inclined with respect to the third direction.

7. The laser chamber according to claim 2, wherein
when the cathode discharge surface has a first discharge surface on the upstream side of the laser gas relative to the axis and has a second discharge surface on the downstream side of the laser gas relative to the axis,
a cross-sectional shape of the first discharge surface has a linear shape inclined with respect to the third direction, and
a cross-sectional shape of the second discharge surface has a linear shape parallel to the third direction or inclined with respect to the third direction.

8. The laser chamber according to claim 1, wherein
the anode discharge surface is a part of an elliptical shape which has an ellipticity in a range of ⅙ to ¼ and is flattened in the second direction.

9. The laser chamber of claim 1, wherein
the cathode electrode and the anode electrode are formed of a material containing copper.

10. The laser chamber according to claim 1, wherein
a coating film is formed on the anode discharge surface.

11. The laser chamber according to claim 10, wherein
a material of the coating film is a mixture of copper and ceramic.

12. A discharge electrode to be used in a gas laser apparatus that excites a laser gas containing fluorine by electric discharge, the discharge electrode comprising:
a cathode electrode including a cathode discharge surface extending in a first direction; and
an anode electrode including an anode discharge surface extending in the first direction and disposed in such a posture that the anode discharge surface faces the cathode discharge surface in a second direction orthogonal to the first direction,
a cross-sectional shape of the cathode discharge surface cut along a plane orthogonal to the first direction being asymmetrical about an axis parallel to the second direction, and a cross-sectional shape of the anode discharge surface cut along the plane being symmetrical about the axis, in an initial state.

13. The discharge electrode according to claim 12, wherein
a corner of the cathode discharge surface on an upstream side of the laser gas is located farther away from a discharge space between the cathode electrode and the anode electrode in the second direction than a corner of the cathode discharge surface on a downstream side of the laser gas.

14. The discharge electrode according to claim 13, wherein
when the cathode discharge surface has a first discharge surface on the upstream side of the laser gas relative to the axis and has a second discharge surface on the downstream side of the laser gas relative to the axis, a curvature of the first discharge surface is larger than a curvature of the second discharge surface.

15. The discharge electrode according to claim 14, wherein
a cross-sectional shape of the first discharge surface is a part of an elliptical shape which has an ellipticity in a range of ⅕ to ⅓ and is flattened in the second direction, and
a cross-sectional shape of the second discharge surface is a part of an elliptical shape which has an ellipticity in a range of 1/10 to ⅛ and is flattened in the second direction.

16. The discharge electrode according to claim 14, wherein
the cross-sectional shape of the cathode discharge surface is a part of an elliptical shape which is centered on a point positioned on the downstream side of the laser gas relative to the axis, has an ellipticity in a range of ⅕ to ⅓, and is flattened in the second direction.

17. The discharge electrode according to claim 14, wherein
a cross-sectional shape of the first discharge surface is a part of an elliptical shape which has an ellipticity in a range of ⅕ to ⅓ and is flattened in the second direction, and
a cross-sectional shape of the second discharge surface has a linear shape parallel to a third direction orthogonal to the first direction and the second direction or inclined with respect to the third direction.

18. The discharge electrode according to claim 13, wherein
when the cathode discharge surface has a first discharge surface on the upstream side of the laser gas relative to the axis and has a second discharge surface on the downstream side of the laser gas relative to the axis,
a cross-sectional shape of the first discharge surface has a linear shape parallel to a third direction orthogonal to the first direction and the second direction or inclined with respect to the third direction, and
a cross-sectional shape of the second discharge surface has a linear shape parallel to the third direction or inclined with respect to the third direction.

19. The discharge electrode according to claim 12, wherein
the anode discharge surface is a part of an elliptical shape which has an ellipticity in a range of ⅙ to ¼ and is flattened in the second direction.

20. An electronic device manufacturing method comprising:
generating a laser beam with a gas laser apparatus, the gas laser apparatus including
a laser chamber used in the gas laser apparatus that excites a laser gas containing fluorine by electric discharge, the laser chamber including
a cathode electrode including a cathode discharge surface extending in a first direction,
an anode electrode including an anode discharge surface extending in the first direction and disposed in such a posture that the anode discharge surface faces the cathode discharge surface in a second direction orthogonal to the first direction,
a fan configured to circulate the laser gas so as to pass through a discharge space between the cathode electrode and the anode electrode in a third direction orthogonal to the first direction and the second direction, and
a preionization electrode disposed on an upstream side of the laser gas relative to the cathode electrode and the anode electrode,
a cross-sectional shape of the cathode discharge surface cut along a plane orthogonal to the first direction being asymmetrical about an axis parallel to the second direction, and a cross-sectional shape of the anode discharge surface cut along the plane being symmetrical about the axis, in an initial state;
outputting the laser beam to an exposure apparatus; and
exposing a photosensitive substrate to the laser beam within the exposure apparatus to manufacture an electronic device.
